(19) United States
(12) Patent Application Publication
(10) Pub. No.: US 2008/0206915 A1
(43) Pub. Date: Aug. 28, 2008

(54) MANUFACTURING METHOD FOR DISPLAY DEVICE

(75) Inventor: Shunpei YAMAZAKI, Tokyo (JP)

Correspondence Address: NIXON PEABODY, LLP, 401 9TH STREET, NW, SUITE 900, WASHINGTON, DC, 20004-2128, US

(73) Assignee: SEMICONDUCTOR ENERGY LABORATORY CO., LTD., Atsugi-shi (JP)

(21) Appl. No.: 12/114,937

(22) Filed: May 5, 2008

Related U.S. Application Data
(62) Division of application No. 10/771,421, filed on Feb. 5, 2004.

(30) Foreign Application Priority Data
Feb. 6, 2003 (JP) 2003-029038
Feb. 6, 2003 (JP) 2003-029087

(51) Int. Cl. H01L 33/00; H05H 1/24

(52) U.S. Cl. 438/34; 427/569; 257/E33.001

(57) ABSTRACT

With an interconnected fabrication step using the prior art photolithography, major portions of resist, interconnected material, and process gas necessary during plasma processing are wasted. Furthermore, a pumping means such as a vacuum system is necessary. Therefore, the whole equipment is increased in size. Consequently, as the processed substrate is increased in size, the manufacturing cost is increased. Accordingly, a means consisting of directly spraying the resist and interconnected material as liquid drops on necessary locations over the substrate to delineate a pattern is applied. Also, a means consisting of performing a vapor-phase reaction process such as ashing or etching at or near atmospheric pressure is applied.

### TECHNICAL FIELD

The present invention relates to an insulated-gate field-effect transistor typified by a thin-film transistor (TFT) and to a method of fabricating it.

### BACKGROUND ART

in recent years, flat panel displays (FPDs) typified by liquid crystal displays (LCDs) and EL displays have attracted attention as display devices that replace conventional CRTs. Especially, development of a large area liquid-crystal TVs equipped with an active-matrix-driven, large-sized liquid crystal panel is an important subject on which liquid crystal panel manufacturers should concentrate their efforts.

On an active-matrix-driven liquid crystal panel, thin-film transistors (TFTs) are formed as switching elements. Conventionally, film formation and lithography using vacuum processes have been used to fabricate circuit patterns of thin-film transistors and the like.

Film formation is a technique for depositing a thin film after evacuating the inside of a process chamber to a subatmospheric state by a pump. There are techniques such as CVD (chemical vapor deposition) method, sputtering method, and evaporation method. Photolithography is a technique for shaping a thin film into a desired geometry by fabricating a resist mask by an photolithography machine and etching the portions of the thin film that are not protected by the resist mask.

In a vacuum process, the substrate to be processed is transported into a process chamber. Then, processing including film formation, etching, and ashing is performed after the inside of the process chamber is brought to a vacuum state. Evacuation means is necessary to bring the inside of the process chamber to a vacuum state. The evacuation means is comprised of pumps installed outside the processing system (typified by turbomolecular pump, rotary pump, dry pump, and the like), means for managing and controlling them, piping that connects the pumps with the process chamber to constitute an evacuation system, valves, pressure gauges, flowmeters, and the like. To attach these equipments, the cost of the evacuation system and the space for installing the evacuation system are necessary in addition to the processing apparatus. Therefore, the size and cost of the whole processing system are increased.

Process flow diagrams of photolithography that is the prior art are shown in FIGS. 1(A)-(H), and schematic process step diagrams are shown in FIGS. 1(I)-(O). The process of the photolithography starts with spin-coating a photosensitive resist (photoresist) onto a film that has been deposited over a substrate, so that the resist is spread over the whole surface of the film (FIG. 1(A), (I)). The solvent is evaporated off by prebaking, and the photoresist is cured (FIG. 1(B), (J)). Then, light irradiation is carried out via a photomask to expose the resist (exposure) (FIG. 1(C), (K)). Photoresists include positive photoresist whose portions irradiated with light become soluble in developing solution and negative photoresist whose portions irradiated with light become insoluble in developing solution. FIG. 1 is process flow diagrams of photolithography using a positive resist and schematic process step diagrams. Then, the irradiated photoresist portions are dissolved by the developing solution (FIG. 1(D), (E), (L)). The etch resistance of the photoresist is improved by postbaking (FIG. 1(F), (M)). As a result of the process conducted so far, a resist pattern identical in geometry with the pattern formed on the photomask has been transferred onto the film. Furthermore, using the resist pattern as a mask, the coating portions not protected by the resist pattern are etched (FIG. 1(G), (N)). Finally, the resist pattern used as the mask is peeled off (FIG. 1(H), (O)). Consequently, the film pattern that is identical in geometry with the pattern formed on the photomask can be formed.

### DISCLOSURE OF THE INVENTION

### Problem to be Solved by the Invention

However, with the prior art vacuum process, the volume of the process chamber increases with growth in size of substrates such as the fifth generation (e.g., 1000×1200 mm or 1100×1250 mm) and the sixth generation (e.g., 1500×1800 mm). Therefore, in order to reduce the pressure in the process chamber to a vacuum state, an evacuation system of a larger scale is necessary. This increases the installation area and weight of the system. Furthermore, this creates demands for increased size of plants and buildings and for increased load resistance, thus increasing equipment investments. The time necessary for evacuation is increased. The throughput is increased. In addition, the amounts of used utilities such as electric power, water, and gas and of chemicals are increased. This not only increases the manufacturing cost but also leads to increase in the environmental load.

Furthermore, in the prior art photolithography process, resist film formed on the whole surface of a substrate and films (such as metal and semiconductor films) are almost removed. The ratio of resist film and films remaining on the substrate was about several to tens of percents. Especially, when a resist film is formed by spin application, about 95% is wasted. That is, almost all of the material is discarded. This adversely affects the manufacturing cost in the same as vacuum processes. Besides, this leads to an increase in the environmental load. This tendency becomes more conspicuous with increasing the size of the substrate conveyed along manufacturing lines.

### Means for Solving the Problem

To solve the foregoing problem with the prior art, in the invention, means for directly injecting photoresist onto a film to form a resist pattern has been taken. Furthermore, means for producing a plasma at or near atmospheric pressure and locally performing vapor-phase reaction processes such as film formation, etching, and ashing have been taken.

In the invention, as a means for performing the aforementioned ejection of liquid drops, a liquid drop ejector equipped with a head having dotlike liquid drop ejection holes and a liquid drop ejector equipped with a head having liquid drop ejection holes having linear arrays of dotlike ejection holes are used.

Furthermore, in the invention, as the aforementioned means for performing the vapor-phase reaction processes, a plasma processing apparatus fitted with a plasma generation means at or near atmospheric pressure is used.

The above-described means for spraying liquid drops or partial vapor-phase reaction processes are carried out within atmosphere or near atmospheric pressure. Therefore, the evacuation system which has been required in the prior art vacuum processes and used to evacuate the inside of the process chamber to bring it to a vacuum state can be omitted. Accordingly, the evacuation system that is increased in size with growing the substrate size can be simplified. Hence, the equipment cost can be reduced. Correspondingly, the energy or the like for the evacuation can be suppressed, which leads to a decrease in the environmental load. Furthermore, the time for the evacuation can be omitted. Therefore, the throughput improves and liquid crystal panels can be manufactured more efficiently.

By applying these means, the amounts of resist and films (such as metal and semiconductor) and of gases used in vapor-phase reaction processes, which has been the problem with the prior art, have been reduced greatly.

### ADVANTAGE OF THE INVENTION

By fabricating a display device using the liquid drop ejector having the liquid drop irradiation head on which dotlike liquid drop ejection holes are arranged, the liquid drop ejector having the liquid drop ejection head on which dotlike liquid drop ejection holes are linearly arranged, and the plasma processing apparatus having plasma generation means under atmospheric condition, a waste of the material (the material of interconnects and the like in the liquid drop ejection method and gases in the case of a plasma) can be reduced. At the same time, the manufacturing cost can be reduced. In addition, by using the aforementioned apparatus simplifying the process steps, miniaturizing, reducing in size of manufacturing plant, and machines. In consequence, the fabrication plant can be reduced in size. Also, Shortening can be accomplished. In addition, the equipment of evacuation system that has been required heretofore can be simplified. In this way, the energy can be reduced. Hence, the environmental load can be reduced. Investment costs such as equipment costs have been reduced greatly.

In addition, the invention provides a fabrication process corresponding to large-sized substrates, and solves various problems such as growth in size of equipment and increase in the processing time arising from growth in size of conventional equipment.

### BRIEF DESCRIPTION OF THE DRAWINGS

FIGS. 1(A)-(O) is a diagram illustrating processes of photolithography.

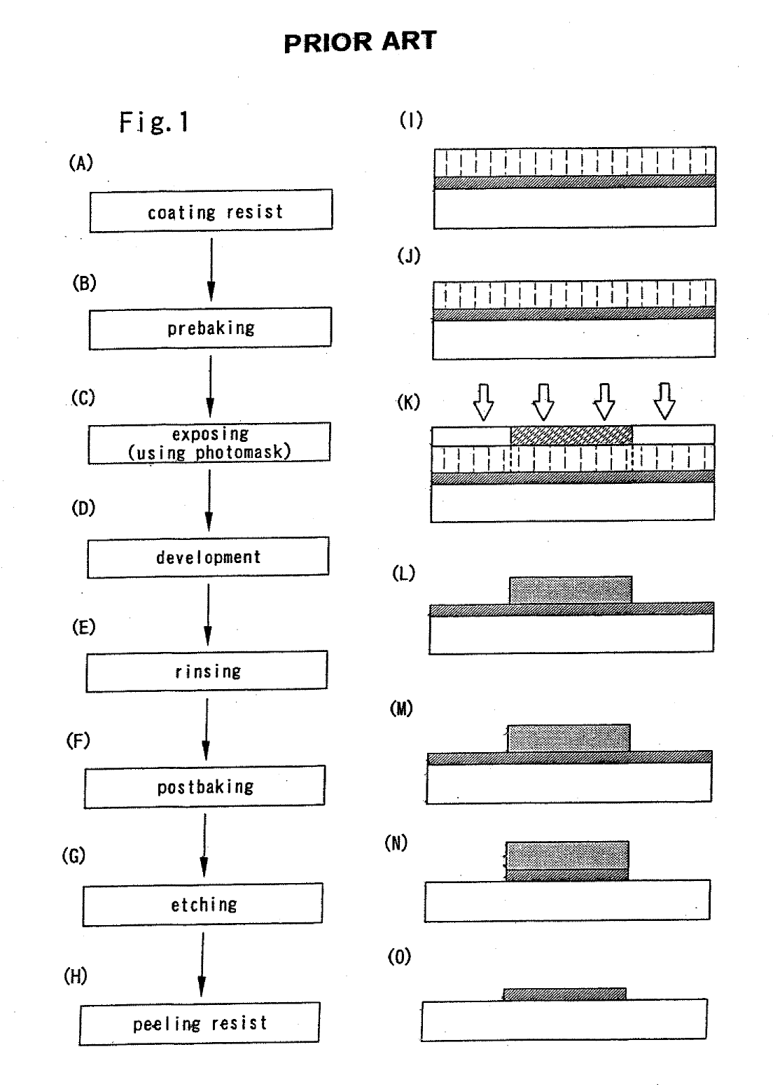

FIGS. 2(A)-(F) is a schematic view of process steps associated with Embodiment Mode 1 of the invention.

FIG. 3 is a view showing a dotlike liquid drop ejector of the invention.

FIG. 4 is a view showing the bottom portion of a head in the dotlike liquid drop ejector of the invention.

FIGS. 5(A)-(F) is a view showing the configuration of a plasma generator portion of an atmospheric-pressure plasma processing apparatus of the invention.

FIGS. 6(A)-(C) is a view showing a linear liquid drop ejector of the invention.

FIGS. 7(A)-(B) is a view showing the bottom portion of a head in the linear liquid drop ejector of the invention.

FIGS. 8(A)-(B) is a view showing the configuration of the plasma generator portion of the atmospheric-pressure plasma processing apparatus of the invention.

FIGS. 9(A)-(D) is a schematic view of process steps associated with Embodiment Mode 4 of the invention.

FIGS. 10(A)-(F) is a schematic view of process steps associated with Embodiment Mode 5 of the invention.

FIGS. 11(A)-(E) is a schematic view of fabrication steps associated with Embodiment 1 of the invention.

FIGS. 12(A)-(F) is a schematic view of fabrication steps associated with Embodiment 1 of the invention.

FIGS. 13(A)-(F) is a schematic view of fabrication steps associated with Embodiment 1 of the invention.

FIGS. 14(A)-(E) is a schematic view of fabrication steps associated with Embodiment 1 of the invention.

FIGS. 15(A)-(E) is a schematic view of fabrication steps associated with Embodiment 1 of the invention.

FIGS. 16(A)-(F) is a schematic view of fabrication steps associated with Embodiment 2 of the invention.

FIGS. 17(A)-(C) is a view showing electronic devices associated with Embodiment 3 of the invention.

### BEST MODE FOR CARRYING OUT THE INVENTION

### Embodiment Mode 1

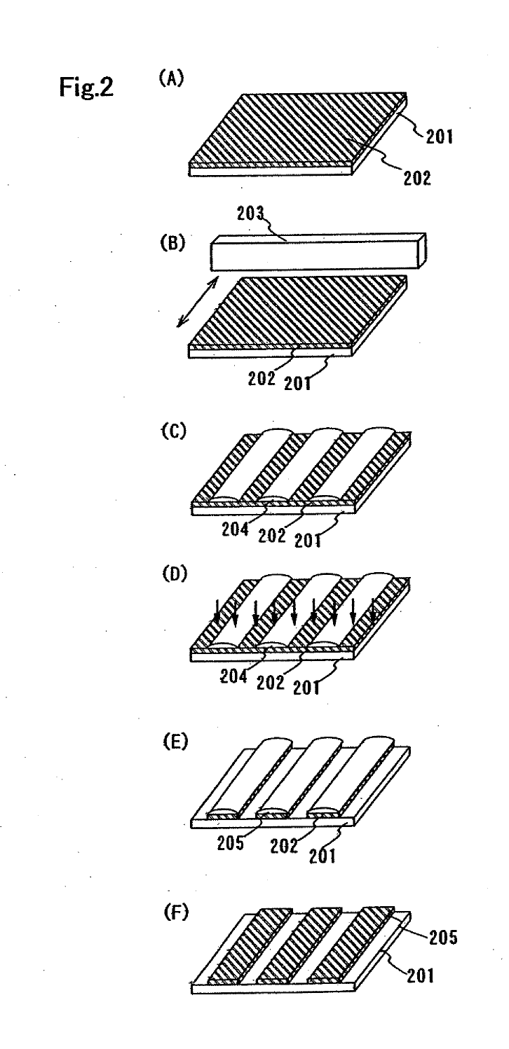

In an Embodiment mode of the invention, an wiring pattern of a semiconductor device on a glass substrate of a desired size is formed by using liquid drop ejectors and a plasma processing apparatus having a plasma generation means at or near atmospheric pressure. The invention is especially intended for application to a substrate of increasing in size such as of the fifth generation (e.g., 1000×1200 mm or 1100×1250 mm) or of the sixth generation (e.g., 1500×1800 mm). Embodiment mode 1 of the invention is hereinafter described with reference to FIG. 2 that is an accompanying drawing.

Note that the expression “liquid drop ejectors” simply referred to in Embodiment mode 1 embraces both a liquid drop ejector fitted with a head having dotlike liquid drop ejection holes and a liquid drop ejector fitted with a head having liquid drop ejection holes consisting of linear arrays of dotlike ejection holes.

First, a film 202 is formed over a substrate 201 to be processed, using a well-known method, for example, sputtering or CVD process (FIG. 2(A)). Then, using a liquid drop ejector having a liquid drop ejection head 203 described later, liquid drops are ejected from liquid drop ejection holes such that the drops are overlapping (FIG. 2(B)). That is, the liquid drop ejection head is scanned in the direction of the arrow shown in FIG. 2(B) while ejecting the liquid drops such that they overlap. At this time, by ejecting the liquid drops from the dotlike liquid drop ejection holes such that the drops overlap, a resist pattern 204 is formed like dots or lines (FIG. 2(C)). During the formation of the resist pattern 204, the substrate may be scanned, as well as scanning of the head. Furthermore, not only dotlike and linear forms but also arbitrary shape of resist pattern may be formed by combining scans of the head and substrate. Then, using a baked resist pattern as a mask, the film 202 is etched at or near atmospheric pressure, using a plasma processing apparatus having a plasma generation means described later (FIG. 2(D)). The portions of the film 202 not masked by the resist pattern 204, i.e., the exposed portions of the film 202, are etched by gas (FIG. 2(E)). After etching the film 202, the resist pattern 204 is peeled off. For the peeling of the resist pattern 204, one may use wet processing in which the resist is dissolved in a chemical, ashing (dry processing) using the plasma processing apparatus having the plasma generation means, and a combination of the wet processing and dry processing. As a result, a pattern of the film having the same geometry as that of the resist pattern 204 is formed (FIG. 2(E)). In addition, Oxygen is generally used as the gas during the ashing.

### Embodiment Mode 2

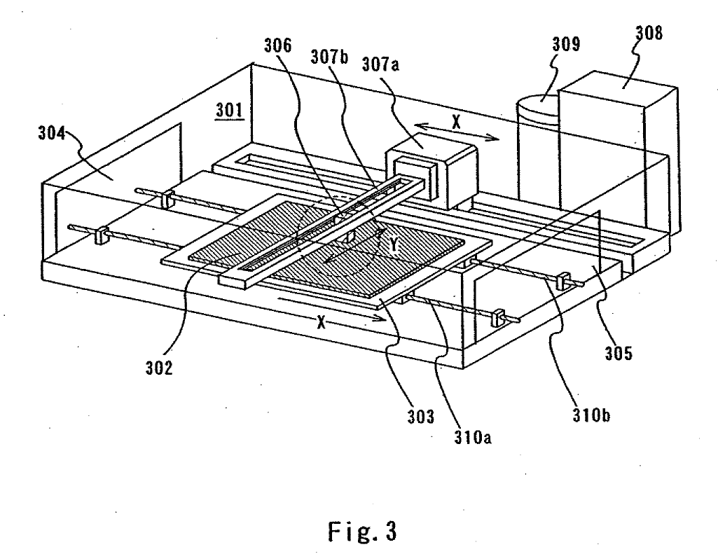

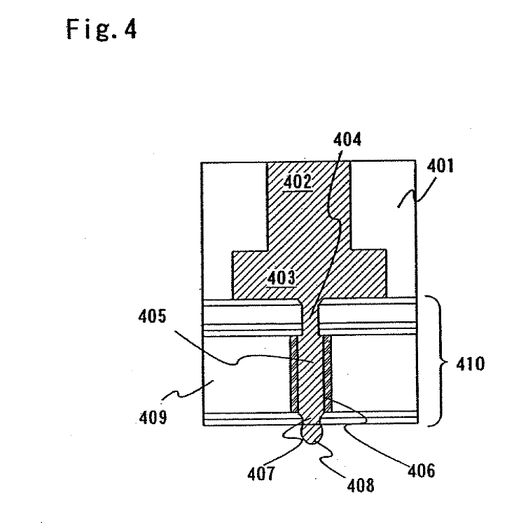

A liquid drop ejector having a liquid drop ejection head in which dotlike liquid drop ejection holes are arranged can be used in Embodiment Mode 1 and is hereinafter described with reference to the accompanying drawings. FIG. 3 is a schematic perspective view showing one example of configuration of the dotlike liquid drop ejector. FIG. 4 is a view showing a head portion in which nozzles are arranged and which is used in this dotlike liquid drop ejector.

The dotlike liquid drop ejector shown in FIG. 3 comprises a head 306 inside the apparatus. A desired pattern of liquid drops is obtained over a substrate 302 by ejecting liquid drops from the head 306. In the present dotlike liquid drop ejector, besides a glass substrate or the like having a desired size, a resin substrate typified by a plastic substrate or an object to be processed such as a semiconductor wafer typified by silicon can be used as the substrate 302.

In FIG. 3, the substrate 302 is transported into a casing 301 from a transport entrance 304. The substrate that has finished liquid drop ejection processing is conveyed out from a transport exit 305. Inside the casing 301 the substrate 302 is installed on a transport stage 303. The transport stage 303 moves on rails 310a and 310b connecting the transport entrance and the transport exit.

Head support portions 307a and 307b provide a mechanism that supports the head 306 for ejecting liquid drops and moves the head 306 to an arbitrary location within an X-Y plane. The head support portion 307a moves in the X-direction parallel to the transport stage 303. The head 306 installed on the head support portion 307b fixed to the head support portion 307a moves in the Y-direction vertical to the X-direction. Simultaneously with the conveyance of the substrate 302 into the casing 301, the head support portion 307a and head 306 move in X- and Y-directions, respectively, and are set in initial given positions at which processing of liquid drop ejection is performed. Movement of the head support portion 307a and head 306 into their initial positions is made when the substrate is transported in or when it is transported out. Thus, processing of ejection can be carried out efficiently.

The processing of liquid drop ejection starts when the substrate 302 reaches a given position at which the head 306 is waiting by movement of the transport stage 303. The processing of liquid drop ejection is achieved by a combination of relative movement among the head support portion 307a, head 306, and substrate 302 and liquid drop ejection from the head 306 supported to the head support portions. A desired pattern of liquid drops can be delineated over the substrate 302 by adjusting the moving speeds of the substrate, head support portions, and head and the period at which liquid drops are ejected from the head 306. Especially, since processing of ejection of liquid drops needs sophisticated accuracy, it is desired that the movement of the transport stage 303 be stopped during ejection of liquid drops and that only the head support portion 307 and head of high controllability be scanned. In driving the head 306 and head support portion 307a, a driving method of high controllability such as a servomotor, pulse motor, or the like is preferably selected. Furthermore, each of the scans of the head 306 and head support portion 307a in the X- and Y-directions is not limited to one direction. The processing of ejection of liquid drops may be performed by making reciprocation or repeated reciprocations. Liquid drops can be sprayed over the whole substrate by the above-described movement of the processed object and head support portion.

The liquid drops are supplied into the casing from a liquid drop supply portion 309 installed outside the casing 301, and are further supplied into a liquid chamber inside the head 306 via the head support portions 307a and 307b. This supply of liquid drops is controlled by a control means 308 installed outside the casing 301. It may also be controlled by a control means incorporated in the head support portion 307a inside the casing.

A main function of the control means 308 is the aforementioned control of liquid drops. Other functions are the control of the movement of the transport stage, the head support portion, and the head and the corresponding control of ejecting liquid drops. Data of pattern delineation by the ejection of liquid drops can be downloaded through software such as CAD from outside of the apparatus. These data are entered by a method such as entry of a figure or entry of coordinates. Furthermore, an automatic function of warning the residual amount may be added by mounting a mechanism for detecting the amount of remaining composition used as liquid drops inside the head 306 and transferring information indicating the remaining amount to the control means 308.

Although not described in FIG. 3, sensors for aligning to the substrate and the pattern over the substrate, a means for introducing gas into the casing, a means for evacuating the inside of the casing, a means for heat-treating the substrate, a means for irradiating the substrate with light, means for measuring temperature, pressure, and various physical property values, and the like may be installed according to the need. Also, these means can be simultaneously controlled in a lump by the control means 308 installed outside the casing 301. Furthermore, the process steps can all be managed from the outside by connecting the control means 308 with a production management system or the like by a LAN cable, wireless LAN, optical fiber, or the like. This leads to improvement of the productivity.

Next, an internal structure of the head 306 is described. FIG. 4 is a cross-sectional view of the head 306 of FIG. 3, taken parallel to the Y-direction.

In FIG. 4, liquid drops supplied into the head 401 from the outside are passed through a liquid chamber flow channel 402 and stored in a preliminary liquid chamber 403. Then, the drops move into a nozzle 409 for ejecting the liquid drops. The nozzle portion comprises a fluid resistance portion 404 mounted such that appropriate liquid drops are loaded into the nozzle, a pressurization chamber 405 for applying pressure to the liquid drops and ejecting them to the outside of the nozzle, and a liquid drop ejection hole 407.

Here, the diameter of the liquid drop ejection hole 407 is set to in a range of 0.1 to 50 μm (preferably, 0.6 to 26 μm). The amount of ejection of the composition ejected from the nozzle is set to in a range of 0.00001 pl to 50 pl (preferably, 0.0001 to 40 pl). This amount of ejection increases in proportion to the size of the diameter of each nozzle. Furthermore, the distance between the object to be processed and the liquid drop ejection hole 407 is preferably set as short as possible to eject the drops to desired locations. Preferably, it is set to about 0.1 to 2 mm. The amount of ejection may also be controlled without varying the diameter of the liquid drop ejection hole 407 by varying the pulse voltage applied to piezoelectric elements. Preferably, these ejection conditions are so set that the linewidth is about 10 μm or less.

Piezoelectric elements 406 which are deformed by application of a voltage and has a piezoelectric effect such as lead zirconate titanate (Pb(Zr,Ti)O₃) or the like are arranged on the sidewall of the pressurization chamber 405. Therefore, the piezoelectric elements are deformed by applying a voltage to the piezoelectric elements 406 arranged in the target nozzles. The internal volume of the pressurization chamber 405 decreases. As a result, the liquid drops are pushed out. The liquid drops 408 can be ejected to the outside.

In the invention, the ejection of the liquid drops is carried out by a so-called piezo method using piezoelectric elements. Depending on the material of the liquid drops, a so-called thermal ink jet method in which liquid drops are pushed out by heating heat-generating bodies to produce air bubbles may be used. In this case, the resulting structure has the heat-generating bodies instead of the piezoelectric elements 406.

Furthermore, in the nozzle portion 410 for ejection of liquid drops, the wettability between the liquid drops and the liquid chamber flow channel 402, preliminary liquid chamber 403, fluid resistance portion 404, pressurization chamber 405, and liquid drop ejection 407 is important. For this reason, a carbon film, resinous film, or the like (not shown) for adjusting the wettability with the material may be formed in each the flow channels.

Liquid drops can be sprayed onto the substrate to be processed by the means described above. Methods of ejection of liquid drops include a so-called sequential method (dispenser method) in which successive liquid drops are ejected to form a successive dotlike pattern and a so-called on-demand method in which liquid drops are ejected like dots. The on-demand method is shown in the instrumental configuration in the invention, but a head using the sequential method can also be used.

Resins such as photoresist and polyimide can also be used as the composition that is employed as the liquid drops of the above-described dotlike liquid drop ejector. If the material acts as a mask during etching of the film, it is not necessary to photosensitive such as photoresist. Furthermore, paste-like metallic materials, organic solutions such as conductive polymer in which the paste-like metal is dispersed, organic solutions such as conductive polymer in which metal material in the form of ultrafine particles and the metal material are dispersed, and the like can be used as the composition that is employed as the liquid drops of the dotlike liquid drop ejector for forming a conductor (conductive layer).

Especially, the metal material in the form of ultrafine particles can be fine particles of several micrometers to submicrometers, ultrafine particles on the order of nanometers, or a one containing both. Where metal material in the form of ultrafine particles on the order of nanometers is used as the composition, it is necessary to select the metal which is in the form of ultrafine particles and small enough to pass into contact holes, narrow grooved portions, and the like.

Photosensitive resist, paste-like metal material, or organic solution of conductive polymer or the like in which the paste-like metal is dispersed can be used as the composition that is employed as the liquid drops of the dotlike liquid drop ejector. Furthermore, metal material in the form of ultrafine particles and an organic solvent of a conductive polymer or the like in which the metal material is dispersed can be used. Especially, the metal material in the form of ultrafine particles can be fine particles of several micrometers to submicrometers, ultrafine particles on the order of nanometers, or a one containing both. Where the metal material in the form of ultrafine particles is used as the composition, it is necessary to select the aforementioned metal material which is in the form of ultrafine particles and small enough to pass into contact holes, narrow grooved portions, and the like through unstraight routes. These liquid drops may be heated and dried when the liquid drops land, using a heating mechanism (not shown) mounted to a substrate transport stage 303. Alternatively, after liquid drops completely land on necessary regions or after all the processing of ejection of liquid drops is completed, the drops may be heated and dried. The aforementioned resist is baked by thermal processing and can be used as a mask during etching. In addition, the organic solution containing the metal material in the form of ultrafine particles can be used as metal interconnects because the organic solution is evaporated off by thermal processing and because the metal in the form of ultrafine particles bonds together.

Furthermore, the viscosity of the composition is preferably equal to less than 20 cp to prevent occurrence of drying and permit smooth ejection of the composition from the ejection ports. In addition, the surface tension of the composition is preferably equal to less than 40 mN/m. Note that the viscosity and the like of the composition may be appropriately adjusted according to the used solvent and application. As an example, the viscosity of a composition prepared by dissolving or dispersing ITO, organic indium, or organic tin in a solvent may be set to in a range of 5 to 20 mPa·S. The viscosity of a composition prepared by dissolving or dispersing silver in a solvent may be set to in a range of 5 to 20 mPa·S. The viscosity of a composition prepared by dissolving or dispersing gold in a solvent may be set to in a range of 5 to 20 mPa·S.

The dotlike liquid drop ejector described so far can be carried out at or near atmospheric pressure unlike resist application step, film formation, and etching step in the prior art photolithography. Near atmospheric pressures indicate a pressure range of from 5 Torr to 800 Torr. Especially, the liquid drop ejector described above can eject liquid drops under a positive pressure of about 800 Torr.

In Embodiment Mode 1 of the invention using the dotlike liquid drop ejector described so far, only required portions of the photoresist pattern are formed. In consequence, the amount of used resist can be reduced greatly compared with the conventionally used spin coating. Furthermore, the process sequence can be simplified because exposing, developing, and rinsing steps can be omitted.

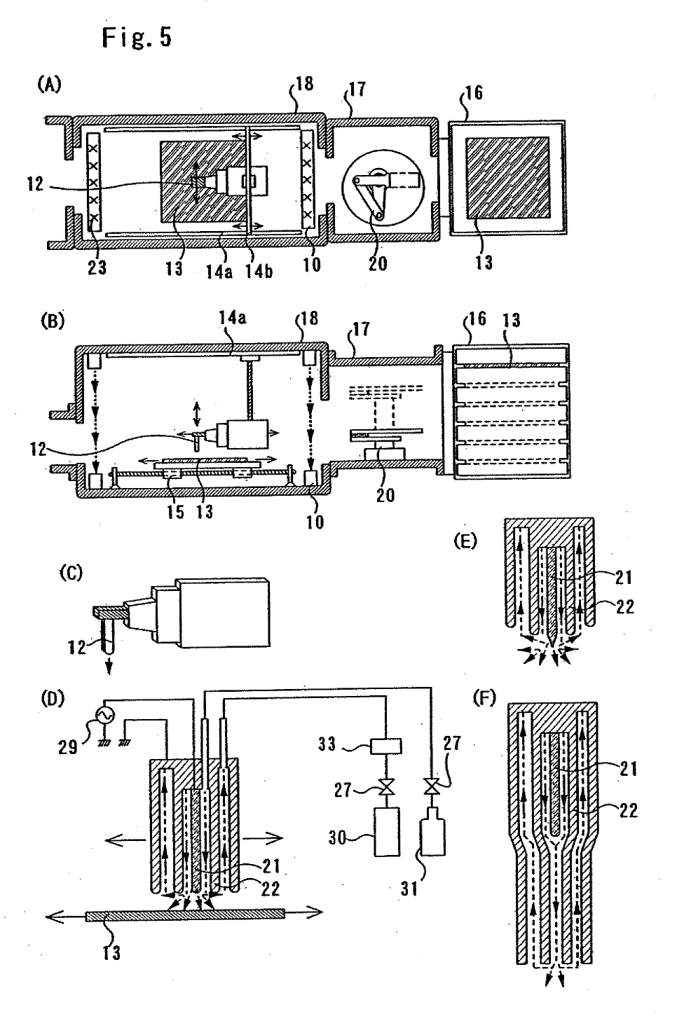

An atmospheric-pressure plasma processing apparatus used in Embodiment Mode 1 is next described by referring to the accompanying drawings. FIG. 5(A) is a top view of one example of the plasma processing apparatus used in the invention. FIG. 5(B) is a cross-sectional view. In the figures, an object 13 to be processed such as a resin substrate typified by glass substrate and plastic substrate of desired size is set in a cassette chamber 16. One example of the method of conveying the object 13 to be processed is horizontal conveyance. Where a substrate of one meter in square of the fifth or newer generation is used, vertical conveyance in which the substrate is placed vertically may be performed in order to reduce the area occupied by the conveyor machine.

In a conveyance chamber 17, the processed object 13 placed in the cassette chamber 16 is conveyed into a plasma process chamber 18 by a conveyance mechanism (robot arm) 20. There are mounted a gas flow control means 10, a plasma generation means 12 having cylindrical electrodes, rails 14a and 14b for moving the plasma generation means 12, a moving means 15 for moving the processed object 13, and the like in the plasma process chamber 18 adjacent to the conveyance chamber 17. If necessary, a well-known heating means (not shown) such as a lamp is mounted.

The gas flow control means 10 is used for dustproofness, and controls gas stream, using inert gas ejected from a blowout port 23 such that isolation from the outside air is achieved. The plasma generation means 12 moves into a given position because of the rail 14a arranged in the direction of conveyance of the processed object 13 and the rail 14b arranged in a direction perpendicular to the direction of conveyance. Also, the processed object 13 is moved in the direction of conveyance by the moving means 15. When plasma processing is performed in practice, either the plasma generation means 12 or the processed object 13 may be moved.

Details of the plasma generation means 12 are next described using FIG. 5(C)-(F). FIG. 5(C) shows a perspective view of the plasma generation means 12 having the cylindrical electrodes. In FIG. 5(D)-(F), cross sections of the cylindrical electrodes are shown.

In FIG. 5(D), the dotted lines indicate the route of gas. Those indicated by 21 and 22 are electrodes comprises a metal having conductivity such as aluminum, copper, or the like. The first electrode 21 is connected with a power supply (RF power supply) 29. A cooling system (not shown) for circulating cooling water may be connected with the first electrode 21. If the cooling system is mounted, heating is prevented in a case where surface processing is performed continuously by circulation of cooling water. This permits improvement of the efficiency owing to continuous processing. The second electrode 22 has a shape that surrounds the periphery of the first electrode 21, and is electrically grounded. Each of the first electrode 21 and second electrode 22 has a cylindrical head provided with nozzle-like thin holes for gas.

The surface of at least one electrode of the first electrode 21 and second electrode 22 is preferably coated with a solid dielectric body. Examples of the solid dielectric body include metal oxides such as silicon dioxide, aluminum oxide, zirconium dioxide, and titanium dioxide, plastics such as polyethylene terephthalate and polytetrafluoroethylene, glass, and composite oxides such as barium titanate. The shape of the solid dielectric body may be sheetlike form or filmlike form. It is preferable that the solid dielectric body in a range of 0.05 to 4 mm in thickness.

A process gas is supplied from a gas supply means (gas cylinder) 31 via a valve 27 into the space between the both electrodes, i.e., the first electrode 21 and second electrode 22. Thus, the ambient atmosphere in this space is replaced. Under this state, if an RF voltage (10 to 500 MHz) is applied to the first electrode 21 by the RF power supply 29, a plasma is produced inside the space. If a stream of reactive gas including chemically active, excited species such as ions and radicals generated by the plasma is directed at the surface of the processed object 13, local plasma surface processing can be performed at given position on the surface of the processed object 13. At this time, the distance between the surface of the processed object 13 and thin ports becoming ejection ports for the process gas is equal to or less than 3 mm, preferably equal to or less than 1 mm, more preferably equal to or less than 0.5 mm. Especially, a sensor for measuring the distance may be mounted, and the distance between the surface of the processed object 13 and the thin holes becoming ejection ports for the process gas may be controlled.

The process gas filled in the gas supply means (gas cylinder) 31 is appropriately set according to the kind of surface processing performed within the process chamber. Exhaust gas is recovered into an exhaust system 30 via a filter 33 for removing dust mixed in the gas and via the valve 27. Moreover, the gas may be used effectively by refining and circulating the recovered exhaust gas to reuse it.

Also, a cylindrical plasma generation means 12 of cross section different from FIG. 5(D) is shown in FIG. 5(E), (F). In FIG. 5(E), the first electrode 21 is longer than the second electrode 22. The first electrode 21 has an acute-angled shape. Also, the plasma generation means 12 shown in FIG. 5(F) has such a shape that the gas stream produced between the first electrode 21 and second electrode 22 and ionized is ejected to the outside.

The invention using a plasma processing apparatus operating under atmospheric pressure or near atmospheric pressure (pressure range of 5 Torr to 800 Torr) does not need a time for pumping necessary for a vacuum system and a time for opening to the atmosphere. It is not necessary to dispose a complex pumping system. Especially, where a large-sized substrate is used, the chamber is inevitably increased in size. If the inside of the chamber is evacuated, the processing time is prolonged. Therefore, the present apparatus operated at or near atmospheric pressure is effective and can reduce the manufacturing cost.

Because of the foregoing, by performing etching of the conductive film and ashing of the resist in Embodiment Mode 1 of the invention, using the above-described atmospheric-pressure plasma processing apparatus, the prior art pumping procedure can be omitted and thus the processing can be performed in a shortened time. Furthermore, since no pumping system is necessary, fabrication can be performed in a space narrower than in the case where an apparatus having the prior art vacuum processing is used.

The dotlike liquid drop ejector of the invention and the atmospheric-pressure plasma processing apparatus of the invention can be used in combination for the step for fabricating interconnect patterns in Embodiment Mode 1 described above. Although either means may be used and the other means may be committed to the prior art means, it is desirable that the above-described dotlike liquid drop ejector of the invention and the atmospheric-pressure plasma processing apparatus of the invention are used in combination if space savings, shortened processing, lower cost, and the like are taken into consideration.

### Embodiment Mode 3

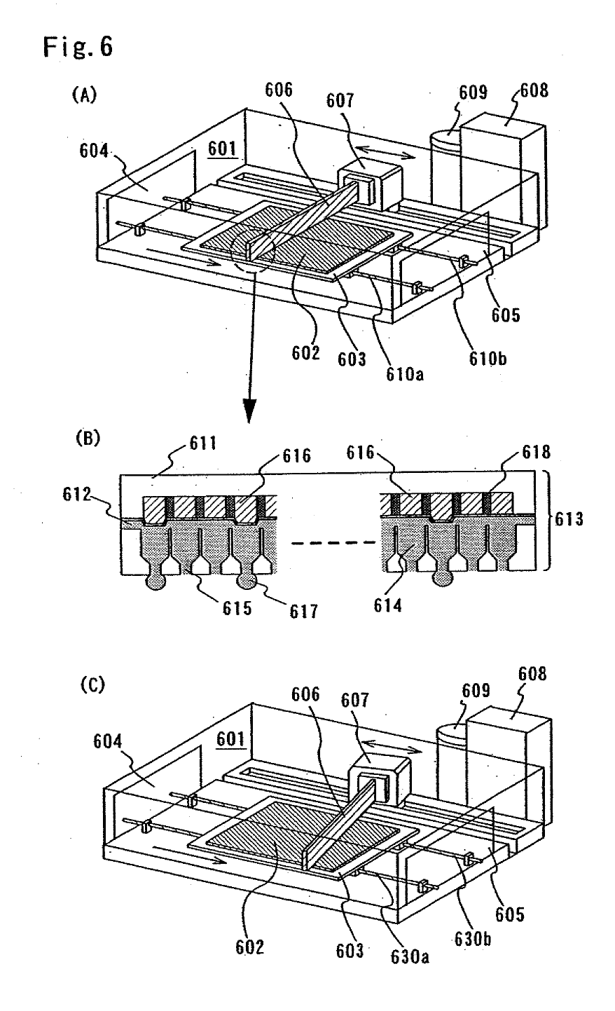

A linear liquid drop ejector that can be used in Embodiment Mode 1 is described with reference to the accompanying drawings. The present apparatus has a liquid drop ejection head in which dotlike liquid drop ejection holes are arranged linearly. FIG. 6(A) is a schematic perspective view showing one example of configuration of the linear liquid drop ejector. Also, FIG. 6(B) is a view showing a head in which nozzles used in this linear liquid drop ejector are arranged.

The linear liquid drop ejector shown in FIG. 6(A) has the head 606 in the apparatus. A desired liquid drop pattern is obtained on a substrate 602 by ejecting liquid drops thereby. In the present linear liquid drop ejector, a glass substrate of desired size can be used as the substrate 602. In addition, a resin substrate typified by a plastic substrate or a semiconductor wafer or the like typified by silicon may also be used as the substrate 602.

In FIG. 6(A), the substrate 602 is conveyed into the casing 601 from a conveyance entrance 604. The substrate that has finished the liquid drop ejection processing is conveyed out from a conveyance exit 605. Inside the casing 601, the substrate 602 is installed on a transport stage 603. The transport stage 603 moves on rails 610a and 610b connecting the transport entrance and transport exit.

A head support portion 607 supports the head 606 that ejects liquid drops, and moves parallel to the transport stage 603. Simultaneously with conveyance of the substrate 602 into the casing 601, the head support portion 607 moves such that the head is aligned with a given position where first liquid drop ejection processing is performed. The processing of ejection can be performed efficiently by moving the head 606 into the initial position when the substrate is conveyed in or when the substrate is conveyed out.

The processing of ejection of liquid drops starts when the substrate 602 arrives at the given position where the head 606 is waiting, because of the movement of the transport stage 603. The processing of ejection of liquid drops is achieved by a combination of relative movement between the head support portion 607 and the substrate 602 and ejection of liquid drops from the head 606 supported to the head support portion. A desired pattern of liquid drops can be delineated over the substrate 602 by adjusting the moving speeds of the substrate and head support portion and the period at which liquid drops are ejected from the head 606. Especially, since processing of ejection of liquid drops needs sophisticated accuracy, it is desired that the movement of the transport stage be stopped during ejection of liquid drops and that only the head support portion 607 of high controllability be scanned sequentially. A driving method of high controllability such as a servomotor, pulse motor, or the like is preferably selected to drive the head 606. Furthermore, the scan made by the head support portion 607 of the head 606 is not limited to one direction. The processing of ejection of liquid drops may be performed by making reciprocation or repeated reciprocations. Liquid drops can be sprayed over the whole substrate because of the above-described movement of the substrate and the head support portion.

The liquid drops are supplied into the casing from a liquid drop supply portion 609 installed outside the casing 601, and are further supplied into a liquid chamber inside the head 606 via the head support portion 607. This supply of liquid drops is controlled by a control means 608 installed outside the casing 601. It may also be controlled by a control means incorporated in the head support portion 607 inside the casing.

A main function of the control means 608 is the aforementioned control of the supply of liquid drops. Other main functions are the control of the movement of the transport stage and head support portion and the corresponding control of the ejection of liquid drops. Also, data about pattern delineation owing to the ejection of liquid drops can be downloaded through software such as CAD from outside of the apparatus. The data are entered by a method such as entry of a figure or entry of coordinates. Furthermore, an automatic function of warning the residual amount may be added by mounting a mechanism for detecting the amount of remaining composition used as liquid drops inside the head 606 and transferring information indicating the remaining amount to the control means 608.

Although not described in FIG. 6(A), sensors for aligning to the substrate and the pattern over the substrate, a means for introducing gas into the casing, a means for evacuating the inside of the casing, a means for heat-treating the substrate, a means for irradiating the substrate with light, means for measuring temperature, pressure, and various physical property values, and the like may be installed according to the need. Also, these means can be simultaneously controlled by the control means 608 installed outside the casing 601. Furthermore, the process steps can all be managed from the outside by connecting the control means 608 with a production management system or the like by a LAN cable, wireless LAN, optical fiber, or the like. This leads to improvement of the productivity.

The internal structure of the head 606 is next described. FIG. 6(B) is a cross-sectional view of the head 606 of FIG. 6(A), taken in the longitudinal direction. The right side of FIG. 6(B) is in communication with the head support portion.

The liquid drops supplied into the head 611 from the outside are passed through a common liquid chamber flow channel 612 and then distributed into nozzles 613 for ejecting the liquid drops. It comprises a pressurization chamber 614 for applying pressure to the liquid drops and ejecting them to the outside of the nozzle and liquid drop ejection holes 615.

Piezoelectric elements 616 which are deformed by application of a voltage and have a piezoelectric effect such as lead zirconate titanate (Pb(Zr,Ti)O₃) or the like are arranged in the pressurization chambers 614, respectively. Therefore, by applying a voltage to the piezoelectric elements 616 arranged in the desired nozzles, liquid drops within the pressurization chambers 614 can be pushed out, and liquid drops 617 can be ejected to the outside. Furthermore, the piezoelectric elements are electrically isolated from an insulator 618 in contact with them. Therefore, they are not electrically contacted with each other. Ejection of individual nozzles can be controlled.

In the invention, the ejection of the liquid drops is carried out by a so-called piezo method using piezoelectric elements. Depending on the material of the liquid drops, a so-called thermal ink jet method in which liquid drops are pushed out by producing air bubbles using heat-generating bodies and applying pressure may be used.

Furthermore, in the nozzles 613 for ejection of liquid drops, the wettability between the liquid drops 617 and the common liquid chamber flow channel 612, pressurization chamber 614, and liquid drop ejection holes 615 is important. For this reason, a carbon film, resinous film, or the like (not shown) for adjusting the wettability with the material may be formed on the inner surfaces of the common liquid chamber flow channel 612, pressurization chamber 614, and liquid drop ejection holes 615.

Because of the means described above, liquid drops can be sprayed over the substrate to be processed. Methods of ejection of liquid drops include a so-called sequential method (dispenser method) in which successive liquid drops are ejected to form a continuous linear pattern and a so-called on-demand method in which liquid drops are ejected like dots. The on-demand method is shown in the instrumental configuration in the invention. An instrumental configuration using ejection utilizing the sequential method is also possible.

FIG. 6(C) is an instrumental configuration having the head support portion 607 of FIG. 6(B) fitted with a rotating mechanism. By operating the head support portion 607 at an angle to a direction perpendicular to direction in which the substrate is scanned, liquid drops can be ejected at shorter distances than the distances between the adjacent liquid drop ejection holes in the liquid drop ejection holes arranged in the head 606. The transport stage 603 moves on rails 630a and 630b connecting the transport entrance and transport exit.

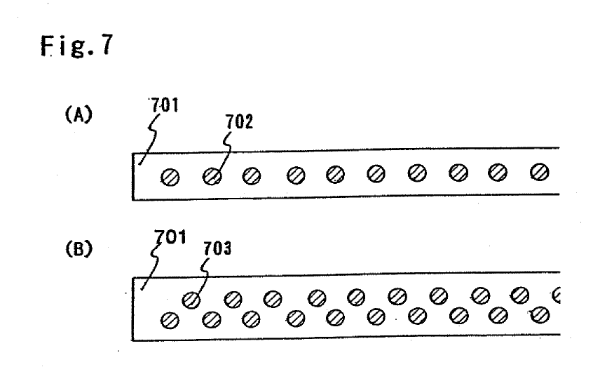

FIG. 7(A), (B) is a schematic representation of the bottom portion of the head 606 in FIG. 6. FIG. 7(A) is a fundamental one in which liquid drop ejection holes 702 are arranged linearly on the head 701 bottom surface. In contrast, in FIG. 7(B), there are two arrays of liquid drop ejection holes 703 in the head bottom portion 701. The arrays are arranged such that they are shifted with respect to each other by a distance equal to half of the pitch. If the liquid drop ejection holes are arranged as in FIG. 7(B), a film pattern can be formed without providing a mechanism for making scans in the direction perpendicular to the direction of scan of the substrate, the film pattern being continuous in the direction. This permits the film to be shaped into an arbitrary form.

Furthermore, the above-described liquid drops may be sprayed over the substrate 602 at an angle. The tilt may be done by a tilting mechanism fitted to the head 606 or head support portion 607. The shape of the liquid drop ejection holes 615 in the head 611 may be tilted, and liquid drops may be ejected at an angle. Thus, the shape when the liquid drops land over the substrate can be controlled by controlling the wettability with the liquid drops sprayed over the surface of the substrate 602.

Photoresist, polyimide, or other resin can also be used as the composition used as liquid drops of the above-described linear liquid drop ejector apparatus. If the material becomes a mask when the film is etched, it is not necessary that the material be photosensitive like photoresist. Furthermore, paste-like metal material, organic solution of conductive polymer or the like in which the paste-like metal is dispersed, organic solution of conductive polymer or the like in which a metal material in the form of ultrafine particles and the metal material are dispersed, and the like can be used. Especially, the metal material in the form of ultrafine particles can be fine particles of several micrometers to submicrometers, ultrafine particles on the order of nanometers, or a one containing both. Where metal material in the form of ultrafine particles on the order of nanometers is used as the composition, it is necessary to select the ultrafine particles of the metal material which can sufficiently pass into contact holes, narrow grooved portions, and the like.

The ejected liquid drops may be heated and dried when they land, using a heating mechanism (not shown) mounted to a substrate transport stage 603. Alternatively, after liquid drops completely land on necessary regions or after all the processing of ejection of liquid drops is completed, the drops may be heated and dried. The photoresist can be used as a mask during etching by thermal processing. Further, interconnect patterns can be formed by ejection of liquid drops by using a paste-like metal material, an organic solvent comprising the paste-like metal, or an organic solvent or the like comprising a metal material in the form of ultrafine particles and the metal material. In addition, the organic solvent comprising the metal material in the form of ultrafine particles forms metal interconnects because the organic solvent is evaporated off by thermal processing and because the metal in the form of ultrafine particles bonds together.

In Embodiment Mode 1 of the invention using the linear liquid drop ejector described so far, the photoresist pattern is formed on only required portions. In consequence, the amount of used resist can be reduced greatly compared with the conventionally used spin application. Furthermore, the process sequence can be simplified because exposing, developing, and rinsing steps can be omitted.

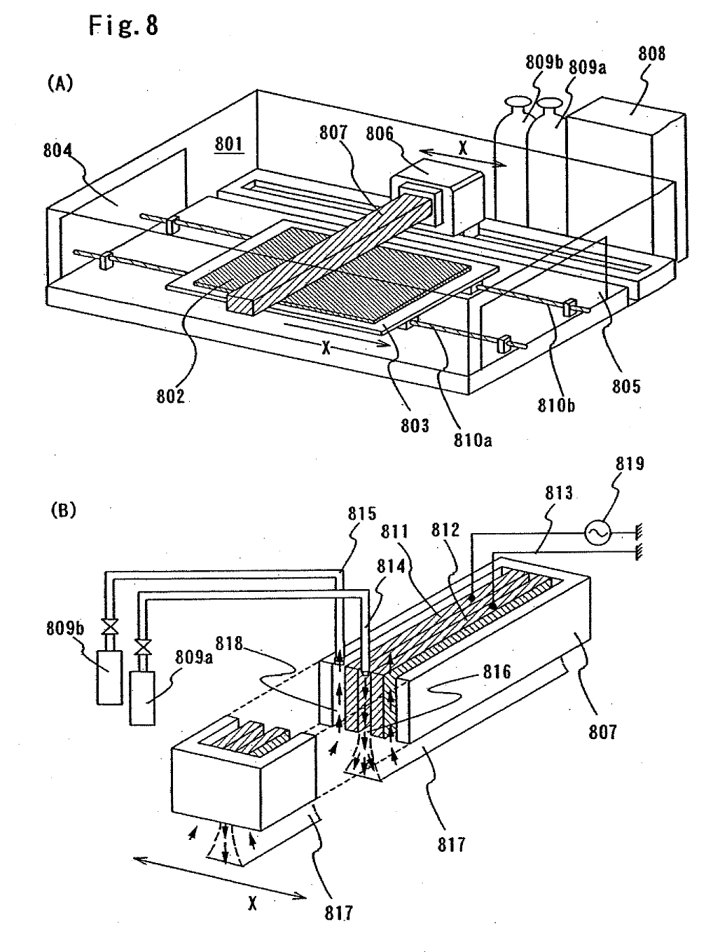

A plasma processing apparatus having a plasma generation means at or near atmospheric pressure used in Embodiment Mode 1 is next described with reference to the accompanying drawings. FIG. 8 is a perspective view of the plasma processing apparatus used in the invention. In the present plasma processing apparatus, a glass substrate of desired size can be used as the substrate 802. In addition, a resin substrate typified by a plastic substrate or a semiconductor wafer typified by silicon may also be used as the substrate 802. One example of the method of conveying the substrate 802 is horizontal conveyance. Where a large-sized substrate of the fifth generation (e.g., 1000×1200 mm or 1100×1250 mm) or the sixth generation (e.g., 1500×1800 mm) is conveyed, vertical conveyance in which the substrate is placed vertically may be performed in order to reduce the area occupied by the conveyor machine.

In FIG. 8(A), the substrate 802 is transported into the casing 801 of the plasma processing apparatus from a transport entrance 804. The substrate that has finished plasma surface processing is conveyed out from a transport exit 805. Inside the casing 801, the substrate 802 is installed on a transport stage 803. The transport stage 803 moves over rails 810a and 810b connecting the transport entrance 804 and the transport exit 805.

A plasma generation means 807 having parallel-plate electrodes, a movable support mechanism 806 for moving the plasma generation means 807, and the like are mounted inside the casing 801 of the plasma processing apparatus. Also, as the need arises, a well-known gas flow control means such as an air curtain or a well-known heating means (not shown) such as a lamp is mounted.

The plasma generation means 807 moves into a given position as the movable support mechanism 806 supporting the plasma generation means 807 moves parallel to the rails 810a and 810b arranged in the direction of conveyance of the substrate 802. Also, the transport stage 803 moves over the rails 810a and 810b and thus the substrate 802 also moves. When plasma processing is performed in practice, the plasma generation means 807 and the substrate 802 may be relatively moved. One of them may be made stationary. Plasma processing actually performed may be plasma surface-processing of the whole surface of the substrate 802 by making relative movement between the plasma generation means 807 and the substrate 802 while producing a plasma continuously. The plasma surface processing may be carried out by producing a plasma only at an arbitrary location over the substrate 802.

Details of the plasma generation means 807 are next described using FIG. 8(B). FIG. 8(B) is a perspective view showing the plasma generation means 807 having the parallel-plate electrodes.

In FIG. 8(B), the arrows 816 and 818 indicate the route of gas. Those indicated by 811 and 812 are electrodes comprised a conductive substance typified by a metal having conductivity such as aluminum, copper, or the like. The first electrode 811 is connected with a power supply (RF power supply) 819. A cooling system (not shown) for circulating cooling water may be connected with the first electrode 811. If the cooling system is mounted, heating is prevented in a case where surface processing is performed continuously by circulation of cooling water. This permits improvement of the efficiency owing to continuous processing. The second electrode 812 is identical in shape with the first electrode 811, and is arranged parallel. The second electrode 812 is electrically grounded as shown at 813. The first electrode 811 and second electrode 812 form thin linear openings for gas in lower-end portions placed parallel.

The surface of at least one electrode of the first electrode 811 and second electrode 812 is preferably coated with a solid dielectric body. If there are portions of the electrodes which are directly opposite to each other without being coated with the solid dielectric body, an arc discharge will be produced therefrom. Examples of the solid dielectric body include metal oxides such as silicon dioxide, aluminum oxide, zirconium dioxide, and titanium dioxide, plastics such as polyethylene terephthalate and polytetrafluoroethylene, glass, and composite oxides such as barium titanate. The shape of the solid dielectric body may be sheetlike form or filmlike form. Preferably, the thickness is in a range of 0.05 to 4 mm.

A process gas is supplied from a gas supply means (gas cylinder) 809a via a valve and a pipe 814 into the space between the both electrodes, i.e., the first electrode 811 and second electrode 812. If in a range of 10 to 500 MHz is applied to the process gas in the ambient of the space between the both electrodes, a plasma is produced inside the space. If a stream of reactive gas including chemically active, excited species such as ions and radicals generated by the plasma is directed at the surface of the substrate 802 (817), given plasma surface processing can be performed over the surface of the substrate 802. At this time, the distance between the surface of the substrate 802 and the plasma generation means 807 is preferably equal to or less than 0.5 mm. Especially, a sensor for measuring the distance may be mounted, and the distance between the surface of the processed substrate 802 and the plasma generation means 807 may be controlled.

The process gas filled in the gas supply means (gas cylinder) 809a is appropriately set according to the kind of surface processing performed within the process chamber. Exhaust gas is recovered into an exhaust system 809b via a pipe 815, a filter (not shown) for removing dust mixed in the gas, valves, and the like. Moreover, the gas may be used effectively by refining the recovered exhaust gas and circulating it to reuse it.

The invention using a plasma processing apparatus operating at or near atmospheric pressure (pressure range of 5 Torr to 800 Torr) shortens the time taken for pumping necessary for a pressure decrease and the time required for opening to the atmosphere. It is not necessary to dispose a complex pumping system. Especially, where a large-sized substrate is used, the chamber is also inevitably increased in size. If the inside of the chamber is evacuated, the processing time is also prolonged. Therefore, the present apparatus operated at or near atmospheric pressure is effective and can reduce the manufacturing cost.

Because of the foregoing, if etching of the thin film and ashing of the resist in the Embodiment Mode of the invention are performed, using the above-described atmospheric-pressure plasma processing apparatus, fabrication could be done with reduced installation area compared with the case where an apparatus having the prior art pumping system is used, because no pumping system is necessary. Since the pumping procedure can be omitted, processing can be performed in a shorter time than conventional processing. In addition, the amounts of used utilities such as electric power, water, and gas and of chemicals are suppressed. This has reduced the manufacturing cost.

The above-described linear liquid drop ejector and the plasma processing apparatus can be used in combination in the step for fabricating film patterns in Embodiment Model described above. Although either means may be used and the other may be committed to the prior art means, it is desirable that the both apparatus are used in combination if space savings, shortened processing, lower cost, and the like are taken into consideration. Furthermore, the dotlike liquid drop ejector and plasma processing apparatus shown in Embodiment Mode 2 can be used in combination.

### Embodiment Mode 4

Embodiment Mode 4 of the invention fabricates a film pattern on a substrate, especially an interconnected pattern for TFTs. In the present Embodiment Mode, interconnections are selectively formed over the substrate without using photoresist.

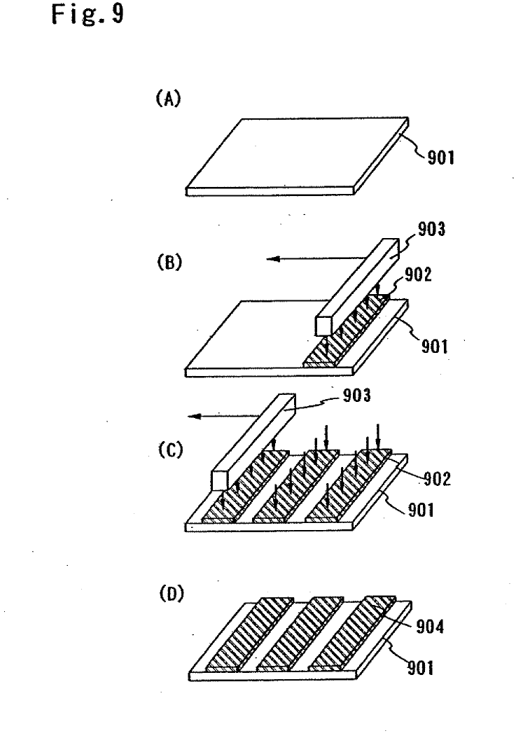

A substrate 901 is prepared (FIG. 9(A)). A conductive film 902 is selectively formed by the plasma processing apparatus having the plasma generation means at or near atmospheric pressure used in Embodiment Mode 1 (FIG. 9(B)). The selective etching of the conductive film is done by producing a plasma only on portions of the conductive film where a film is to be formed while making a relative motion between the substrate 901 and plasma generation means 903 in the direction of the arrow (in the left direction in the figure) in FIG. 9(C). An interconnected pattern 904 is formed from the conductive film in this way (FIG. 9(D)).

In Embodiment Mode 4 of the invention, the step of forming the resist pattern shown in Embodiment Mode 1 is omitted. The process sequence can be simplified accordingly. However, there is no resist pattern. Therefore, the width of formed interconnections is greatly affected by the diameter of reactive gas ejection holes in the atmospheric-pressure plasma processing apparatus. Accordingly, Embodiment Mode 4 is adapted for formation of an interconnected pattern having an interconnection width at which the effects of the diameter of the reactive gas ejection holes can be neglected.

Because of the fabrication sequence for the interconnected pattern described so far, the prior art pumping procedure for evacuating the inside of the chamber is omitted in the same way as in Embodiment Mode 1. Processing can be performed in a shorter time. Furthermore, since no pumping system is necessary, fabrication can be performed in a narrower space than in the case where a system for evacuating the inside of the chamber is used as in the prior art. In addition, since a plasma is produced selectively, the amount of used reactive gas can be made smaller than conventional amount.

### Embodiment Mode 5

Embodiment Mode 5 of the invention forms a film pattern over a substrate using a photoresist. After etching the film, the resist is removed by performing ashing continuously.

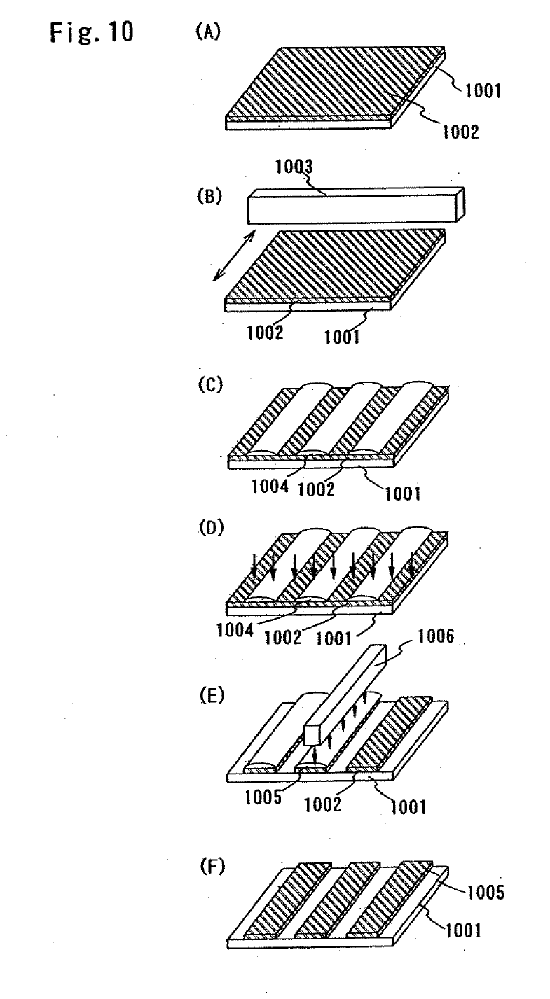

The present Embodiment Mode is described with reference to FIG. 10. FIG. 10(A) to FIG. 10(D) are the same as the steps of FIG. 2(A) to FIG. 2(D) in Embodiment Mode 1. First, using a well-known method (e.g., sputtering or CVD method), a film 1002 is formed over a substrate 1001 to be processed (FIG. 10(A)). Then, a pattern 1004 of photoresist is formed over the film 1002 using a dotlike or linear liquid drop ejector having a liquid drop ejection head 1003 (FIG. 10(B) to FIG. 10(C)). Then, using the baked resist pattern as a mask, the film 1002 is etched, using a plasma processing apparatus having a plasma generation means at or near atmospheric pressure (FIG. 10(D)). The portions of the film 1002 not masked by the resist pattern 1004, i.e., the exposed portions of the film 1002, are etched by the gas. Then, the pattern 1004 of the photoresist is ashed by using plasma generation means (FIG. 10(E)). By ashing the pattern 1004 of the photoresist, a pattern 1005 of the film is formed (FIG. 10(F)). At this time, a plasma may be produced selectively on portions where the pattern of the photoresist is present.

Because of the fabrication sequence described so far, the prior art pumping procedure for evacuating the inside of the chamber is omitted in the same way as in Embodiment Mode 1 and Embodiment Mode 4. The processing can be performed in a short time. Furthermore, since no pumping system is necessary, fabrication can be performed in a narrower space than in the case where a system for evacuating the inside of the chamber is used as in the prior art. In addition, a plasma is produced selectively. Therefore, the amount of used reactive gas can be made smaller than conventional amount. Additionally, the photoresist is peeled off by performing ashing. Consequently, the sequence can be progressed faster than the prior art sequence.

### Embodiment 1

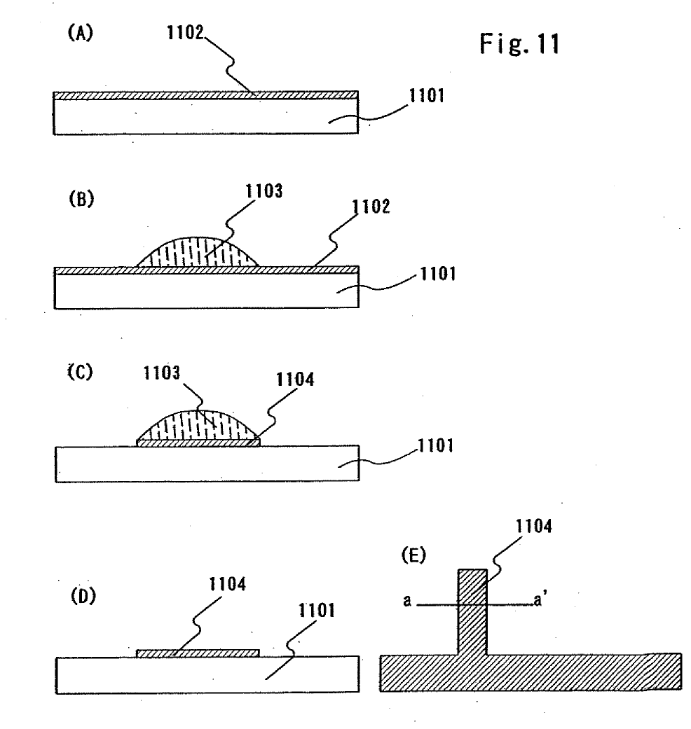

A method of fabricating a display device of the invention using a dotlike or linear liquid drop ejector and a plasma processing apparatus having a plasma generation means at or near atmospheric pressure is described. An embodiment of the invention is hereinafter described with reference to FIGS. 11 to 15. Embodiment 1 of the invention is a method of fabricating channel stop type thin-film transistors (TFTs).

A conductive film 1102 is formed over a substrate 1101 to be processed by a well-known technique, the substrate comprises various materials including glass, quartz, semiconductor, plastic, plastic film, metal, glass-epoxy resin, and ceramic (FIG. 11(A)). Photoresist 1103 is sprayed onto necessary locations over the conductive film by a linear liquid drop ejector of the invention (FIG. 11(B)). Then, the portions of the conductive film not coated with the photoresist are etched (FIG. 11(C)). At this time, the etching may be done by a plasma processing apparatus having a plasma generation means at and near atmospheric pressures used in the Embodiment Mode. The conductive film 1102 is etched. Preferably, the pattern of photoresist is formed such that the linewidth of gate electrodes and interconnections 1102 is about in a range of 5 to 50 μm. At this time, capacitive electrodes and interconnections are formed at the same time.

The pattern of the gate electrodes and interconnects has been formed without using a photomask. Depending on the width of the gate electrodes and interconnections, a finer photoresist pattern may be formed by performing exposure and development using a photomask after the pattern of the photomask is formed by a liquid drop irradiation apparatus.

The conductive film 1102 may be formed by a plasma processing apparatus having a plasma generation means at and near atmospheric pressures used in the Embodiment Mode. In this case, it is not necessary to form a photoresist pattern by a liquid drop ejector.

Then, the resist is peeled off by ashing, using an atmospheric-pressure plasma processing apparatus of the invention (FIG. 11(D)). The peeling of the resist is not limited to ashing. Wet processing using a chemical or a combination of ashing and wet processing may also be used. Obviously, the resist peeling described hereinafter may all be wet processing or a combination of ashing and wet processing.

Gate electrodes and interconnections 1102 and capacitive electrodes and interconnections (not shown) are formed by the process steps described so far. A conductive material such as molybdenum (Mo), titanium (Ti), tantalum (Ta), tungsten (W), chromium (Cr), aluminum (Al), copper (Cu), aluminum (Al) comprising neodymium (Nd), laminated layers thereof, or an alloy thereof can be used as the material forming the gate electrodes and interconnections 1102 and capacitive electrodes and interconnections (not shown).

A top view at this time is shown in FIG. 11(E). FIG. 11(D) corresponds to a cross-sectional view on a-a′ of FIG. 11(E).

Then, a gate insulator film 1201 is formed by a well-known method such as a CVD method (chemical vapor deposition method) or the like. In the present embodiment, a silicon nitride film is formed by a CVD method under atmospheric pressure as the gate insulator film 1201. A silicon oxide film or a laminated layer structure thereof may also be formed.

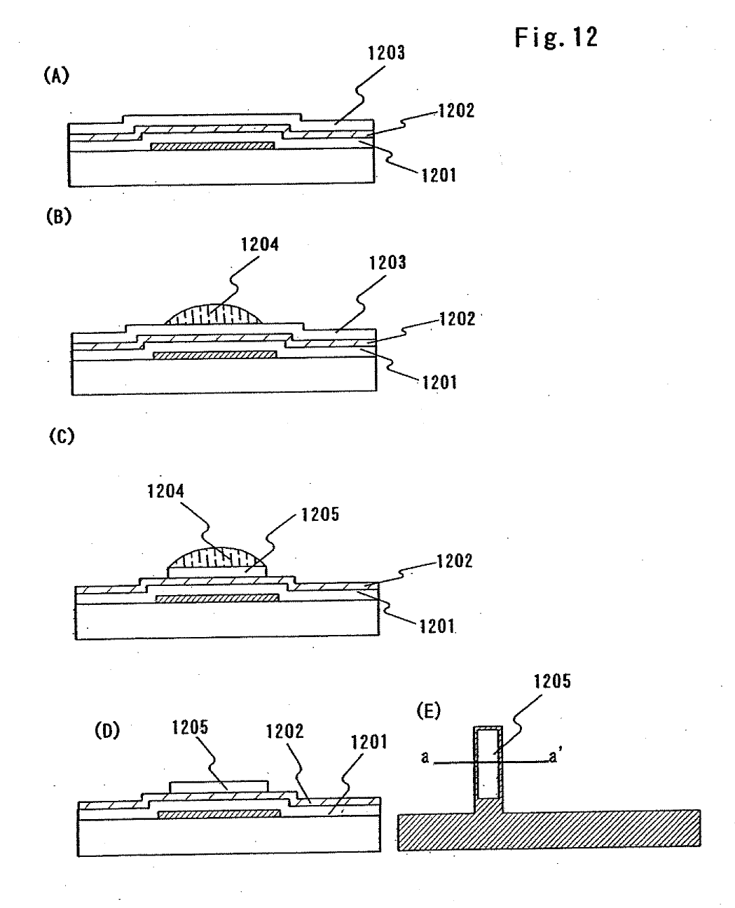

Furthermore, an active semiconductor layer 1202 and a silicon nitride film 1203 are formed in a range of 25 to 80 nm in thickness (preferably, in a range of 30 to 60 nm) by a well-known method (sputtering method, LP (low pressure) CVD method, plasma CVD method, or the like) (FIG. 12(A)). Preferably, the gate insulator film 1201, the active semiconductor layer 1202, and silicon nitride film 1203 are continuously subjected to grown film-formation without opening the inside of the chamber to the atmosphere. The active semiconductor layer 1202 is an amorphous semiconductor film typified by an amorphous silicon film. The silicon nitride film 1203 may be a silicon oxide film and a laminated layer of a silicon nitride film and a silicon oxide film.

Then, photoresist 1204 is formed by a linear liquid drop ejector (FIG. 12(B)). Using the photoresist 1204 as a mask, the portions of the silicon nitride film not coated with the photoresist are etched to form a protective film 1205 (FIG. 12(C)). At this time, the etching may be done by a plasma processing apparatus having a plasma generation means at and near atmospheric pressures used in the Embodiment Mode. The protective film 1205 may be formed by a plasma processing apparatus having a plasma generation means at and near atmospheric pressures used in the Embodiment Mode. In this case, it is not necessary to form a pattern of photoresist by a liquid drop ejector.

Then, the resist is peeled off by ashing by the use of an atmospheric-pressure plasma processing apparatus of the invention (FIG. 12(D)). The peeling of the resist is not limited to ashing. Wet processing using a chemical or a combination of ashing and wet processing is also possible.

A top view at this time is shown in FIG. 12(E). FIG. 12(D) corresponds to a cross-sectional view on a-a′ of FIG. 12(E).

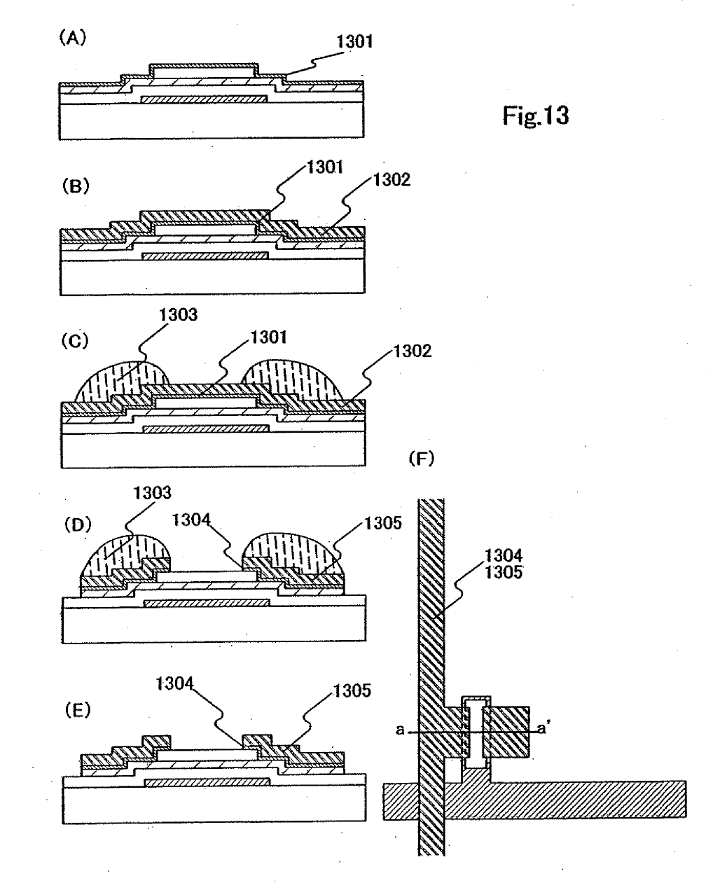

Subsequently, an amorphous semiconductor film 1301 (FIG. 13(A)) doped with an impurity element that imparts N conductivity type and a conductive film 1302 (FIG. 13(B)) are formed over the whole surface of the substrate to be processed.

Then, a pattern 1303 of photoresist is formed using a linear liquid drop ejector of the invention (FIG. 13(C)). Then, the portions of the conductive film, amorphous semiconductor film doped with the impurity element imparting N conductivity type, and active semiconductor layer which are not coated with the photoresist are etched to form source/drain regions 1304, source/drain electrodes, and interconnections 1305 (FIG. 13(D)). At this time, the etching may be done by a plasma processing apparatus having a plasma generation means at and near atmospheric pressure used in the Embodiment Mode. In a channel formation portion, the protective film 1205 prevents the active semiconductor layer under the protective film from being etched.

The linewidth of the source/drain regions 1304, source/drain electrodes, and interconnections 1305 is delineated at in a range of 5 to 25 μm, A conductive material such as molybdenum (Mo), titanium (Ti), tantalum (Ta), tungsten (W), chromium (Cr), aluminum (Al), copper (Cu), aluminum (Al) comprising neodymium (Nd), laminated layers thereof, or an alloy thereof can be used as the material forming the source/drain electrodes and interconnects 1305. The active semiconductor layer, source/drain regions 1304, source/drain electrodes, and interconnections 1305 may be formed by a plasma processing apparatus having a plasma generation means at and near atmospheric pressure used in Embodiment Mode 1 or shown in Embodiment Mode 1 or Embodiment Mode 2. In this case, it is not necessary to form a pattern of photoresist by a liquid drop ejector.

Then, the resist is peeled off by ashing using the atmospheric-pressure plasma processing apparatus of the invention (FIG. 13(E)). The peeling of the resist is not limited to ashing. Wet processing using a chemical or a combination of ashing and wet processing is also possible.

A top view at this time is shown in FIG. 13(F). FIG. 13(E) corresponds to a cross-sectional view on a-a′ of FIG. 13(F).

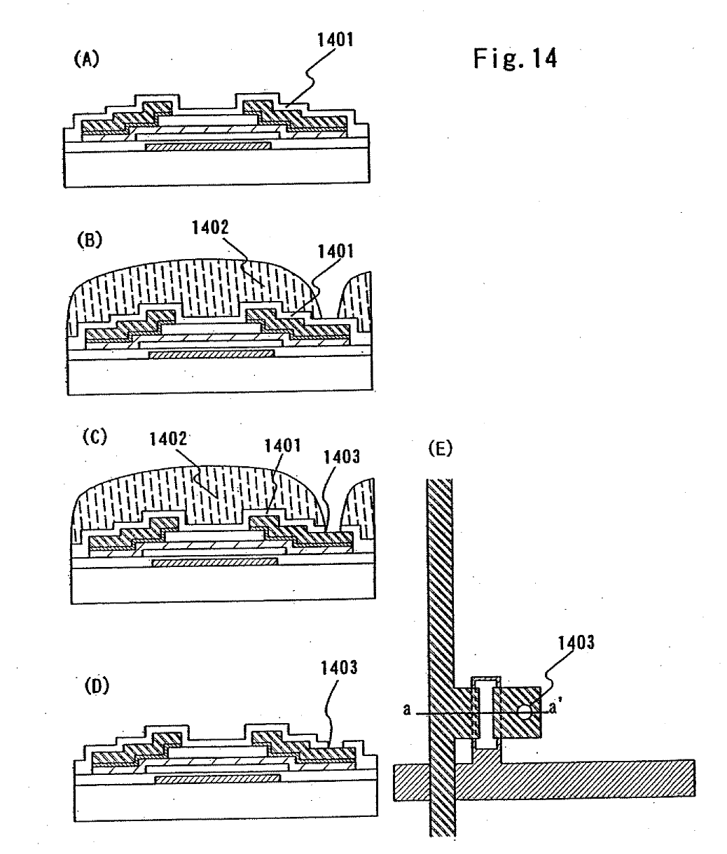

Furthermore, a protective film 1401 is formed by a well-known method such as a CVD method (FIG. 14(A)). In the present embodiment, a silicon nitride film is formed as the protective film 1401 by a CVD method under atmospheric pressure. It may also be a silicon oxide film or a laminated structure thereof. Also, an organic resin film such as acrylic film can also be used.

Then, photoresist is ejected from a linear liquid drop ejector to form a pattern 1402 (FIG. 14(B)). Furthermore, a linear plasma is produced using the plasma processing apparatus having the plasma generation means under atmospheric pressure, and the protective film 1401 is etched. Contact holes 1403 are formed (FIG. 14(C)). At this time, the etching may be done by a plasma processing apparatus having a plasma generation means at and near atmospheric pressure used in the Embodiment Mode. Preferably, the diameter of the contact holes 1403 is set to about in a range of 2.5 to 30 μm by adjusting the RF voltage or the like applied to the gas stream or between the electrodes.

Then, the resist is peeled off by ashing by the use of the atmospheric-pressure plasma generator of the invention (FIG. 14(D)). The peeling of the resist is not limited to ashing. Wet processing using a chemical or a combination of ashing and wet processing may also be used.

A top view at this time is shown in FIG. 14(E). FIG. 14(D) corresponds to a cross-sectional view on a-a′ of FIG. 14(E).

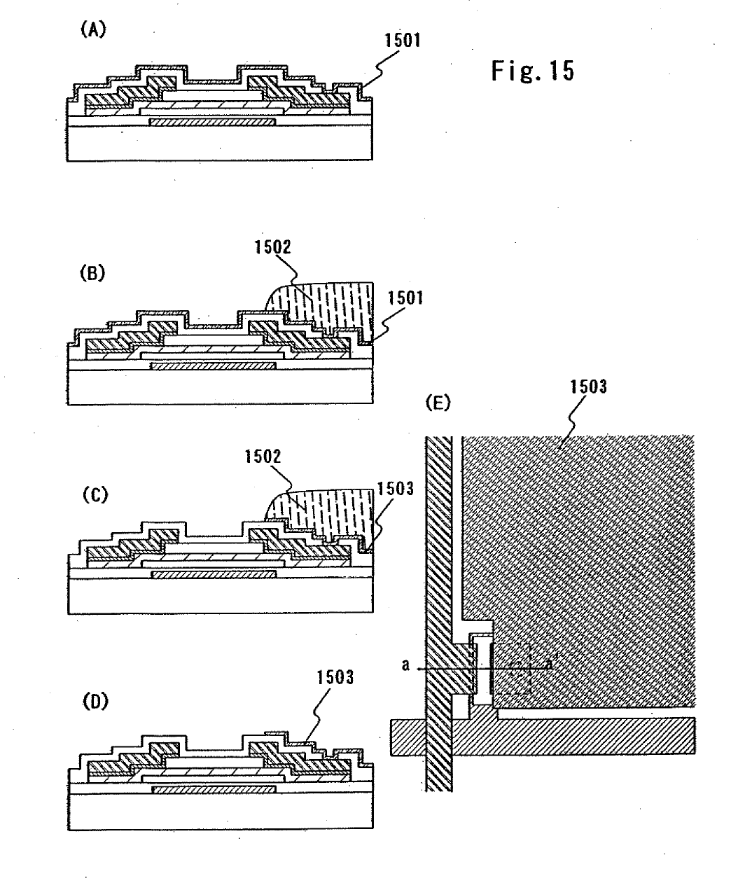

Furthermore, a light transparent conductive film 1501 of ITO or the like is formed by a well-known method such as a CVD method (FIG. 15(A)). Then, photoresist is ejected from a linear liquid drop ejector to form a pattern 1502 (FIG. 15(B)). Further, a linear plasma is produced using the plasma processing apparatus having the plasma generation means under atmospheric pressure, and the light transparent conductive film is etched to form pixel electrodes 1503 (FIG. 15(C)). At this time, the etching may be done by the plasma processing apparatus having the plasma generation means at and near atmospheric pressure used in the Embodiment Mode. The material of the pixel electrodes 1503 is a transparent conductive film of ITO (indium oxide-tin oxide alloy), indium oxide-zinc oxide alloy (In₂O₃)—ZnO), zinc oxide (ZnO), or the like. In addition, a conductive material such as molybdenum (Mo), titanium (Ti), tantalum (Ta), tungsten (W), chromium (Cr), aluminum (Al), copper (Cu), aluminum (Al) comprising neodymium (Nd), laminated layers thereof, or an alloy thereof can be used.

Then, the resist is peeled off by ashing, using an atmospheric-pressure plasma processing apparatus of the invention (FIG. 15(D)). The peeling of the resist is not limited to ashing. Wet processing using a chemical or a combination of ashing and wet processing may also be used.

A top view at this time is shown in FIG. 15(E). FIG. 15(D) corresponds to a cross-sectional view on a-a′ of FIG. 15(E).

In the present Embodiment 1, an example of fabrication of channel stop type thin-film transistors has been shown. Obviously, channel etched type thin-film transistors using no channel stop film can be fabricated by the aforementioned apparatus.

As shown in the present Embodiment 1, the display device in Embodiment 1 of the invention can be fabricated without using a photomask if the dotlike or linear liquid drop ejector according to the invention and the plasma processing apparatus having the plasma generation means at and near atmospheric pressure are used.

In the present Embodiment 1, an example in which channel stop type thin-film transistors are fabricated without using a photomask that has been used in the prior art photolithography process has been shown. Obviously, channel etched type thin-film transistors using no protective film can be fabricated by the use of the dotlike or linear liquid drop ejector according to the invention and the plasma processing apparatus having the plasma generation means at and near atmospheric pressure.

In Embodiment 1, a method of fabricating a display device using an amorphous semiconductor film has been shown. A display device using a crystalline semiconductor typified by polysilicon can also be fabricated using a similar fabrication method.

The display devices using the aforementioned amorphous semiconductor and crystalline semiconductor film are liquid crystal displays. A similar fabrication method may be applied to a self-luminous display (EL (electroluminescent) display).

### Embodiment 2

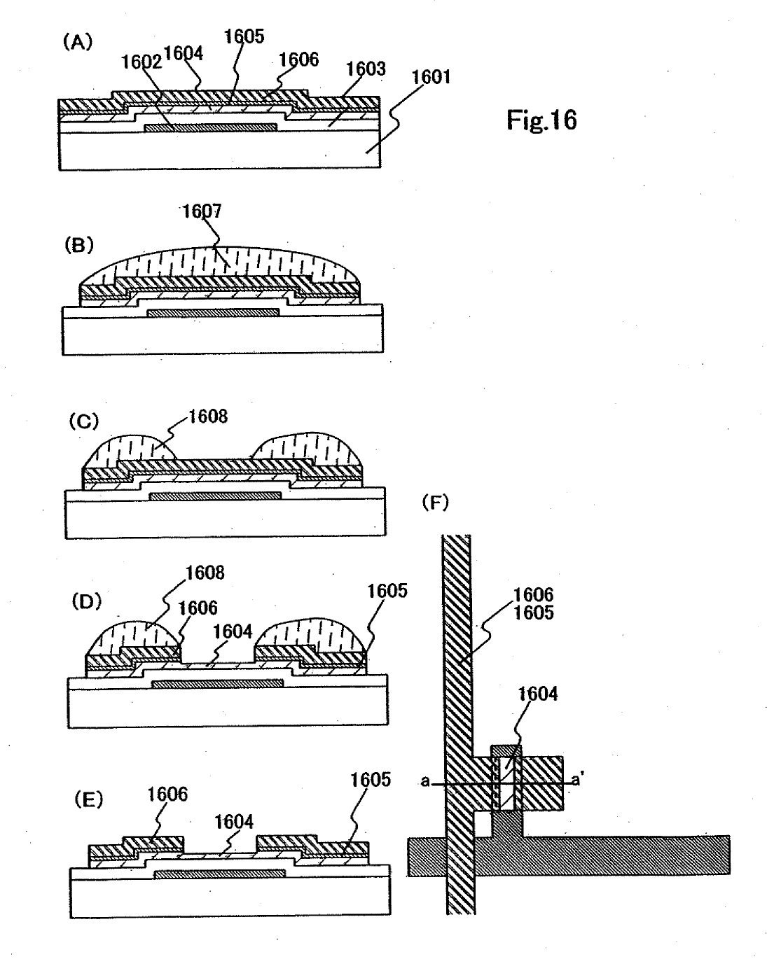

A method of fabricating a display device of the invention using a dotlike or linear liquid drop ejector and a plasma processing apparatus having a plasma generation means at or near atmospheric pressure is described. Embodiment 2 of the invention is hereinafter described with reference to FIG. 16. Embodiment 2 of the invention is a method of fabricating channel etched type thin-film transistors (TFTs). Note that those which are common with the method of fabrication of channel stop type thin-film transistors (TFTs) shown in Embodiment 1 will be appropriately described using FIGS. 11-15.

Gate electrodes and interconnections 1602 and capacitive electrodes and interconnections (not shown) are formed over a substrate 1601 to be processed, using the method described in FIG. 11. A conductive material such as molybdenum (Mo), titanium (Ti), tantalum (Ta), tungsten (W), chromium (Cr), aluminum (Al), copper (Cu), aluminum (Al) comprising neodymium (Nd), laminated layers thereof, or an alloy thereof can be used as the material forming the gate electrodes and interconnects 1602 and capacitive electrodes and interconnections (not shown).

Then, a gate insulator film 1603 is formed by a well-known method such as a CVD method (chemical vapor deposition method) or the like. In the present embodiment, a silicon nitride film is formed by a CVD method under atmospheric pressure as the gate insulator film 1603. A silicon oxide film or a laminated layer structure thereof may also be formed.

Furthermore, an active semiconductor layer 1604 is formed in a range of 25 to 80 nm in thickness (preferably, 30 to 60 nm) by a well-known method (sputtering method, LP (low-pressure) CVD method, plasma CVD method, or the like). Subsequently, an amorphous semiconductor film 1605 doped with an impurity element that imparts N conductivity type and a conductive film 1606 are formed over the whole surface of the processed substrate 1601 (FIG. 16(A)).

Then, photoresist 1607 is formed by a dotlike or linear liquid drop ejector. Using the photoresist 1607 as a mask, the portions of the active semiconductor layer 1604, amorphous semiconductor film 1605, and conductive film 1606 which are not coated with the photoresist are etched and patterned (FIG. 16(B)).

Then, the resist 1607 is peeled off by ashing by the use of an atmospheric-pressure plasma processing apparatus of the invention. The peeling of the resist is not limited to ashing. Wet processing using a chemical or a combination of ashing and wet processing is also possible. Furthermore, photoresist 1608 is formed by a dotlike or linear liquid drop ejector. Subsequently, etching is done using the photoresist as a mask. The portions of the conductive film and amorphous semiconductor film that are not coated with the resist are removed, the amorphous semiconductor film being doped with an impurity element that imparts N conductivity type. Thus, the active semiconductor layer is exposed. In this way, the source/drain regions 1605 and source/drain electrodes and interconnections 1606 are formed (FIG. 16(D)).

Then, the resist 1608 is peeled off by ashing, using an atmospheric-pressure plasma processing apparatus of the invention. The peeling of the resist is not limited to ashing. Wet processing using a chemical or a combination of ashing and wet processing may also be used (FIG. 16(E)).

A top view at this time is shown in FIG. 16(F). FIG. 16(F) corresponds to a cross-sectional view on a-a′ of FIG. 16(E).

Then, a display device using channel etched type thin-film transistors can be fabricated through the process sequence described using FIGS. 14 and 15 in Embodiment 1.

As shown in the present Embodiment 2, the display device in Embodiment 2 of the invention can be fabricated without using a photomask if the dotlike or linear liquid drop ejector according to the invention and the plasma processing apparatus having the plasma generation means at and near atmospheric pressure are used.

In the present Embodiment 2, a method of fabricating a display device using an amorphous semiconductor film has been shown. A display device using a crystalline semiconductor typified by polysilicon can also be fabricated using a similar fabrication method.

The display devices using the aforementioned amorphous semiconductor and crystalline semiconductor film are liquid crystal displays. A similar fabrication method may be applied to a self-luminous display (EL (electroluminescent) display).

### Embodiment 3

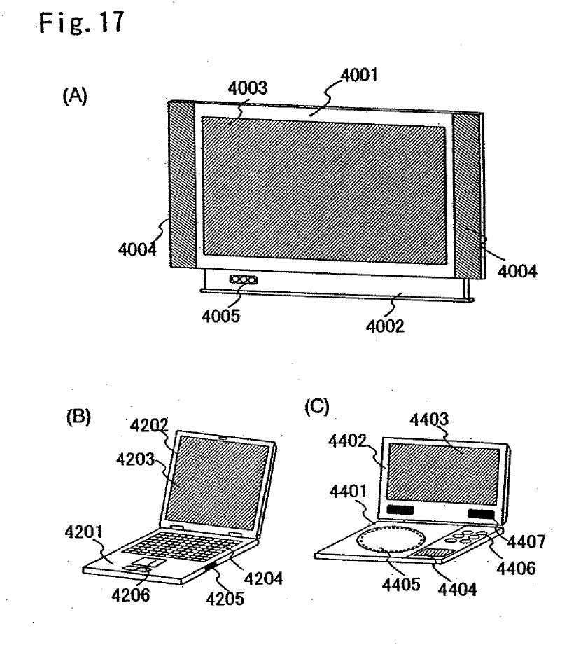

Various electronic apparatus can be completed using the invention. Their specific examples are described using FIG. 17.

FIG. 17(A) is a display device having a large-sized display portion of in a range of 20 to 80 inches, for example, and includes an casing 4001, a support stage 4002, a display portion 4003, speaker portions 4004, a video input terminal 4005, etc. The invention is applied to the fabrication of the display portion 4003. Such a large-sized display device is preferably fabricated using a large-sized substrate of one meter in square of the so-called fifth generation (1000×1200 mm²), sixth generation (1400×1600 m²), or seventh generation (1500×1800 mm²) from a point of view of productivity or cost.

FIG. 13(B) is a notebook type personal computer, and includes a body 4201, an casing 4202, a display portion 4203, a keyboard 4204, an external connection port 4205, a pointing mouse 4206, and the like. The invention is applied to fabrication of the display portion 4203.

FIG. 13(C) is a portable type image reproduction apparatus (in particular, DVD player) equipped with a recording medium, and includes a body 4401, an casing 4402, a display portion A 4403, a display portion B 4404, a recording medium (such as DVD) reading portion 4405, control keys 4406, speaker portions 4407, and the like. The display portion A 4403 mainly displays image information. The display portion B 4404 mainly displays character information. The invention is applied to fabrication of these display portions A and B, 4403 and 4404.

As described so far, the invention is applied to a quite wide range. The invention can be applied to fabrication of electric appliances in all fields. Furthermore, it can be combined with the above-described Embodiment Mode and embodiments at will.

### Embodiment 4

The present embodiment uses a composition comprising of an organic solvent in which fine metal particles are dispersed to form an interconnected pattern. Fine metal particles having an average grain diameter of in a range of 1 to 50 nm, preferably 3 to 7 nm, are used.

Typically, they are fine particles of silver or gold. The surface is coated with a dispersant of amine, alcohol, thiol, or the like. The organic solvent is phenolic resin, epoxy-based resin, or the like. A thermosetting or photosetting resin is applied. The viscosity of the composition may be adjusted by adding a thixotropic agent or dilution solvent.

With respect to an appropriate amount of composition ejected on the formed surface by the liquid drop ejection head, the organic solvent is cured by thermal processing or light irradiation processing. Fine metal particles contact with each other, melt together, fuse together by volume shrink arising from curing of the organic solvent or their agglomeration is accelerated. That is, interconnections in which fine metal particles having an average diameter in a range of 1 to 50 nm, preferably in a range of 3 to 7 nm, have melted together, fused together, or agglomerated are formed. A decrease in the resistance of the interconnections can be accomplished by forming a state in which the fine metal particles make surface contact with each other due to melting, fusing, or agglomeration in this way.

The invention forms an interconnected pattern using such a composition. Consequently, formation of an interconnected pattern having a linewidth of about in a range of 1 to 10 μm is easily facilitated. Similarly, the composition can be filled in the contact holes if their diameters are about 1 to 10 μm. That is, a multilayer interconnected structure can be formed by a fine interconnected pattern.

If fine particles of an insulating substance are used instead of fine metal particles, an insulative pattern can be similarly formed.

Furthermore, the present embodiment can be combined with the above-described Embodiment Mode and embodiments at will.

What is claimed is:

1. A method of fabricating a display device, comprising step of:
selectively forming a film over a substrate to be processed, while moving either or both of a plasma generation means and the substrate to be processed at or near atmospheric pressure by a vapor-phase reaction method.

2. A method of fabricating a display device, comprising step of:
selectively forming a conductive film over a substrate to be processed, while moving either or both of a plasma generation means and the substrate to be processed at or near atmospheric pressure by a vapor-phase reaction method.

3. A method of fabricating a display device, comprising step of:
selectively forming a semiconductor film over a substrate to be processed, while moving either or both of a plasma generation means and the substrate to be processed at or near atmospheric pressure by a vapor-phase reaction method.

4. A method of fabricating a display device as set forth in claim 1, wherein the display device is a liquid crystal or an EL display.

5. A method of fabricating a display device as set forth in claim 2, wherein the display device is a liquid crystal or an EL display.

6. A method of fabricating a display device as set forth in claim 3, wherein the display device is a liquid crystal or an EL display.

7. A method of fabricating a display device, comprising steps of:
forming a first metal film over a substrate;
ejecting drops of resin on the first metal through a head having plural liquid drop ejection holes;
forming a first and a second patterns of resin over the first metal film, by moving the head or the substrate;
etching the first metal film using the first and the second patterns as masks;
removing the first pattern by ashing while the second pattern is not removed;
removing the second pattern by ashing after removing the first pattern;
forming a first insulating film over the first metal film after removing the first and the second patterns;
forming a first semiconductor film over the first insulating film;
forming a second semiconductor film over the first semiconductor film;
ejecting drops of resin on the second semiconductor film through the head having plural liquid drop ejection holes;
forming a third and a fourth patterns of resin over the second semiconductor film, by moving the head or the substrate;
etching the second and the first semiconductor films using the third and the fourth patterns as masks;
removing the third pattern by ashing while the fourth pattern is not removed;
removing the fourth pattern by ashing after removing the third pattern;
forming a second metal film over the second semiconductor film after removing the third and the fourth patterns;
ejecting drops of resin on the second metal film through the head having plural liquid drop ejection holes;
forming a fifth pattern of resin over the second metal film, by moving the head or the substrate;
etching the second metal film using the fifth pattern as a mask; and
etching the second semiconductor film using the fifth pattern as a mask after etching the second metal; and
removing the fifth pattern by ashing.
